(19) United States
(12) Patent Application Publication
(10) Pub. No.: US 2025/0062268 A1
(43) Pub. Date: Feb. 20, 2025

(54) SEMICONDUCTOR PACKAGES HAVING TRENCH STRUCTURES

(71) Applicant: Samsung Electronics Co., Ltd., Suwon-si (KR)

(72) Inventor: Teageon KIM, Suwon-si (KR)

(73) Assignee: Samsung Electronics Co., Ltd., Suwon-si (KR)

(21) Appl. No.: 18/671,541

(22) Filed: May 22, 2024

(30) Foreign Application Priority Data
Aug. 16, 2023 (KR) 10-2023-0106742

(51) Int. Cl. H01L 23/00; H01L 23/538

(52) U.S. Cl. CPC H01L 24/32; H01L 23/5386; H01L 24/29; H01L 24/16; H01L 24/73; H01L 2224/16227; H01L 2224/26175; H01L 2224/32056; H01L 2224/32225; H01L 2224/73204

(57) ABSTRACT

A semiconductor package includes a substrate defining a first trench structure and a second trench structure in an upper surface of the substrate; a semiconductor chip on the substrate; and an underfill filling a space between the substrate and the semiconductor chip. The first trench structure and the second trench structure surround the semiconductor chip. The first trench structure includes at least one first line pattern extending along at least one side surface of the semiconductor chip. The second trench structure includes at least one second line pattern extending along at least one other side surface of the semiconductor chip. A horizontal width of the at least one first line pattern is greater than a horizontal width of the at least one second line pattern.

### CROSS-REFERENCE TO RELATED APPLICATION

This application claims priority under 35 U.S.C. § 119 to Korean Patent Application No. 10-2023-0106742, filed on Aug. 16, 2023, with the Korean Intellectual Property Office, the entirety of which is incorporated herein by reference.

### BACKGROUND

The present disclosure relates to semiconductor packages having a trench structure.

As demand for high performance, high speed, and/or increased multifunctionality of semiconductor devices increases, a degree of integration of semiconductor devices is increasing. When manufacturing fine-patterned semiconductor devices in response to the trend for high integration of semiconductor devices, it is necessary to implement patterns with fine widths or fine spacing. High integration of semiconductor devices mounted on a semiconductor package may be required.

### SUMMARY

The present disclosure relates to a semiconductor package having a substrate in which a first trench structure and a second trench structure are formed in an upper surface thereof.

Example embodiments of the inventive concepts provide a semiconductor package that may include a substrate defining a first trench structure and a second trench structure in a upper surface of the substrate; a semiconductor chip on the substrate; and an underfill filling a space between the substrate and the semiconductor chip. The first trench structure and the second trench structure may surround the semiconductor chip. The first trench structure may include at least one first line pattern extending along at least one side surface of the semiconductor chip. The second trench structure may include at least one second line pattern extending along at least one other side surface of the semiconductor chip. A horizontal width of the at least one first line pattern may be greater than a horizontal width of the at least one second line pattern.

Example embodiments of the inventive concepts further provide a semiconductor package that may include a substrate defining a first trench structure and a second trench structure in an upper surface of the substrate; a semiconductor chip on the substrate; and an underfill filling a space between the substrate and the semiconductor chip. The first trench structure and the second trench structure may surround the semiconductor chip. The first trench structure may include at least one first line pattern extending along at least one side surface of the semiconductor chip. The second trench structure may include at least one second line pattern extending along at least one other side surface of the semiconductor chip. The underfill may include a first buried portion filling the at least one first line pattern and a second buried portion filling the at least one second line pattern. A horizontal width of the first buried portion may be greater than a horizontal width of the second buried portion.

Example embodiments of the inventive concepts may still further provide a semiconductor package that may include a substrate defining a first trench structure and a second trench structure in an upper surface of the substrate; a semiconductor structure on the substrate; chip connection terminals between the substrate and the semiconductor structure; and an underfill filling a space between the substrate and the semiconductor structure and between the chip connection terminals. The first trench structure and the second trench structure may surround the semiconductor structure. The first trench structure may include first line patterns extending along a first side surface and a second side surface of the semiconductor structure, first hole patterns adjacent to a first corner and a third corner of the semiconductor structure, the first hole patterns communicating with the first line patterns, and a second hole pattern communicating with the first line patterns, the second hole pattern adjacent to a second corner of the semiconductor structure. The second trench structure may include second line patterns extending along a third side surface and a fourth side surface of the semiconductor structure, the third side surface opposite to the first side surface and the fourth side surface opposite to the second side surface. A horizontal width of the first line patterns may be greater than a horizontal width of the second line patterns.

### BRIEF DESCRIPTION OF DRAWINGS

The above and other aspects, features, and advantages of the inventive concepts will be more clearly understood from the following detailed description taken in conjunction with the accompanying drawings, in which:

FIG. 1A is a plan view of a semiconductor package according to some example embodiments of the inventive concepts;

FIG. 1B is a partially enlarged view of the semiconductor package illustrated in FIG. 1A;

FIG. 2 is a vertical cross-sectional view along line I-I′ of the semiconductor package illustrated in FIG. 1A;

FIG. 3 is a vertical cross-sectional view taken along line II-II′ of the semiconductor package illustrated in FIG. 1A;

FIGS. 4, 5, 6, 7, 8, 9 and 10 are diagrams illustrating a method of forming an underfill according to some example embodiments;

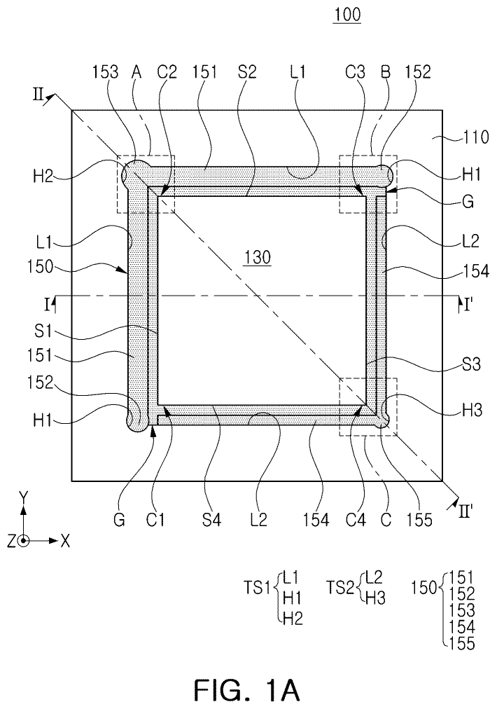

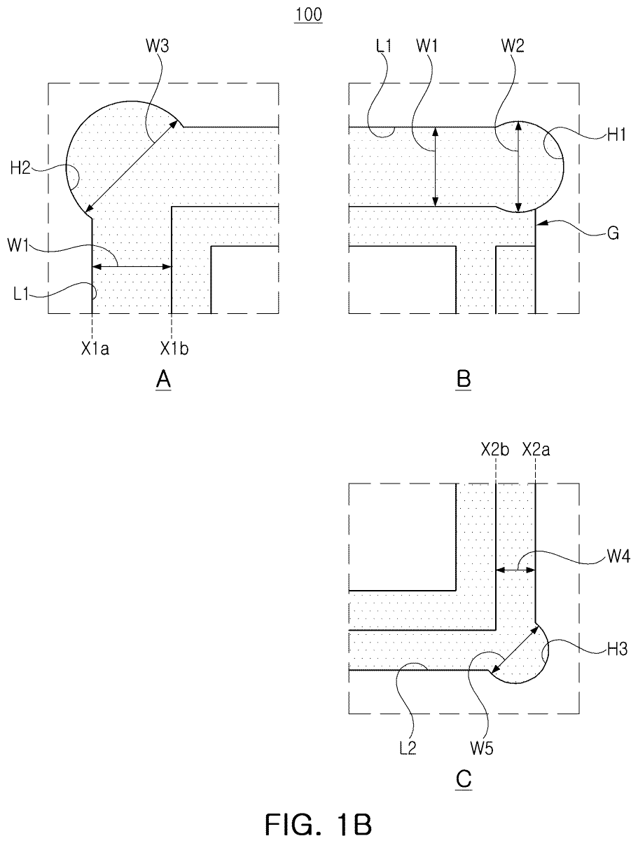

FIG. 1I is a vertical cross-sectional view of a semiconductor package according to some example embodiments.

FIG. 12 is a plan view of a semiconductor package according to some example embodiments.

FIG. 13 is a plan view of a semiconductor package according to some example embodiments;

FIG. 14 is a vertical cross-sectional view taken along line I-I′ of the semiconductor package illustrated in FIG. 13;

FIG. 15 is a plan view of a semiconductor package according to some example embodiments;

FIG. 16 is a plan view of a semiconductor package according to some example embodiments;

FIG. 17 is a plan view of a semiconductor package according to some example embodiments;

FIG. 18 is a vertical cross-sectional view taken along line I-I′ of the semiconductor package illustrated in FIG. 17; and

FIG. 19 is a vertical cross-sectional view of a semiconductor package according to some example embodiments.

### DETAILED DESCRIPTION

Hereinafter, example embodiments of the inventive concepts will be described with reference to the accompanying drawings as follows.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

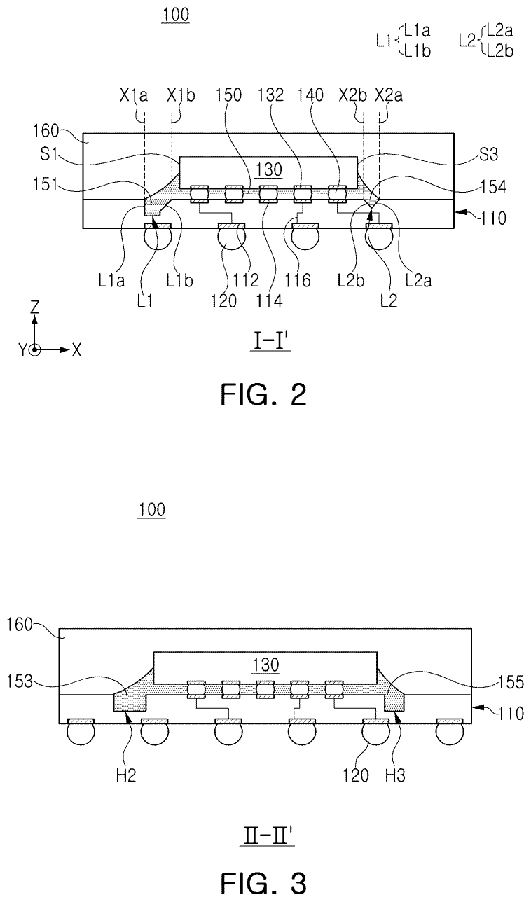

FIG. 1A is a plan view of a semiconductor package according to some example embodiments, FIG. 1B is a partially enlarged view of the semiconductor package illustrated in FIG. 1A, FIG. 2 is a vertical cross-sectional view along line I-I′ of the semiconductor package illustrated in FIG. 1A, and FIG. 3 is a vertical cross-sectional view taken along line II-II′ of the semiconductor package illustrated in FIG. 1A.

Referring to FIGS. 1A to 3, a semiconductor package 100 according to some example embodiments of the inventive concepts may include a substrate 110, an external connection terminal 120, a semiconductor chip 130, a chip connection terminal 140, an underfill 150, and an encapsulant 160.

The substrate 110 may include a lower pad 112, an upper pad 114, and an internal interconnection 116. In some example embodiments, the substrate 110 may be a substrate for a semiconductor package such as a printed circuit board (PCB), an interposer substrate, a ceramic substrate, a tape interconnection board, or the like. For example, the substrate 110 may include a thermosetting resin such as an epoxy resin, a thermoplastic resin such as polyimide, or a photosensitive insulating layer. For example, the substrate 110 may include materials such as prepreg, Ajinomoto Build-up Film® (ABF), FR-4, Bismaleimide Triazine (BT), a Photo Imagable Dielectric Resin (PID), and the like. In some example embodiments, the substrate 110 may be a redistribution substrate used in a wafer-level package or a panel level package. The redistribution substrate may include interconnection layers disposed in layers between insulating layers and vias between the interconnection layers.

The upper pad 114 may be disposed on an upper surface of the substrate 110. The upper pad 114 may be electrically connected to at least one of internal interconnections 116. The lower pad 112 may be disposed on a lower surface of the substrate 110. The lower pad 112 may be electrically connected to at least one of the upper pads 114 through the internal interconnection 116.

The lower pad 112, upper pad 114, and internal interconnection 116 may include conductive materials, such as copper (Cu), aluminum (Al), silver (Ag), tin (Sn), and gold (Au), nickel (Ni), lead (Pb), titanium (Ti), chromium (Cr), tungsten (W), or alloys thereof.

The external connection terminal 120 may be disposed on a lower surface of the substrate 110. The external connection terminal 120 may be electrically connected to the upper pad 114 through the lower pad 112 disposed on the lower surface of the substrate 110. The external connection terminal 120 may be electrically connected to an external device such as a main board, or the like.

In some example embodiments, the semiconductor chip 130 may be electrically connected to the substrate 110 through a chip connection terminal 140. For example, the chip connection terminal 140 may have a flip-chip connection structure having a solder ball, a conductive bump or a grid array such as a pin grid array, a ball grid array, and a land grid array. The semiconductor chip 130 may include a chip pad 132 on a lower surface thereof, and the chip connection terminal 140 may connect a chip pad 132 to the upper pad 114 disposed on the substrate 110.

The chip connection terminal 140 may include at least one of copper (Cu), nickel (Ni), tin (Sn), and an alloy containing tin (Sn—Ag). For example, the chip connection terminal 140 may include a pillar portion connected to the chip pad 132 and a solder portion below the pillar portion. The pillar portion may include at least one of copper (Cu) and nickel (Ni), and the solder portion may include an alloy containing tin (Sn—Ag).

The semiconductor chip 130 may be a logic chip or a memory chip. The logic chip may include a microprocessor, an analog element, or a digital signal processor. The memory chip may include a volatile memory chip such as Dynamic Random Access Memory (DRAM) or Static Random Access Memory (SRAM), and/or a non-volatile memory chip such as Phase-change Random Access Memory (PRAM), Magnetoresistive Random Access Memory (MRAM), Ferroelectric Random Access Memory (FeRAM), or Resistive Random Access Memory (RRAM).

According to some example embodiments of the inventive concepts, the substrate 110 of the semiconductor package 100 may include a first trench structure TS1 and a second trench structure TS2 disposed adjacent to the semiconductor chip 130 on an upper surface thereof. For example, the substrate 110 may be made to define a first trench structure TS1 and a second trench structure TS2 in an upper surface of substrate 110. The first trench structure TS1 and the second trench structure TS2 may extend in a horizontal direction to surround the semiconductor chip 130. The first trench structure TS1 and the second trench structure TS2 may be spaced apart from each other with the semiconductor chip interposed therebetween. For example, the first trench structure TS1 may extend in X and Y-directions along the first side surface S1 and the second side surface S2 of the semiconductor chip 130. The second trench structure TS2 may extend in the X and Y-directions along the third and fourth side surfaces S3 and S4 of the semiconductor chip 130.

In FIG. 1A, it is illustrated that the first trench structure TS1 and the second trench structure TS2 extend along two side surfaces of the semiconductor chip 130, but the inventive concepts are not limited thereto. In some example embodiments, the first trench structure TS1 may extend along one side surface of the semiconductor chip 130 and the second trench structure TS2 may extend along three side surfaces of the semiconductor chip 130, or in some other example embodiments an opposite configuration may also be possible in which the first trench structure TS1 may extend along three side surfaces of the semiconductor chip 130 and the second trench structure TS2 may extend along one side surface of the semiconductor chip 130.

In FIG. 1A, it is illustrated that the first trench structure TS1 and the second trench structure TS2 are spaced apart from the side surfaces of the semiconductor chip 130 at the same distance, respectively, but the inventive concepts are not limited thereto.

In some example embodiments, the first trench structure TS1 may include first line patterns L1, first hole patterns H1, and second hole patterns H2. The first line patterns L1 may have a bar shape in plan view, and may extend in a horizontal direction along the first side surface S1 and the second side surface S2 of the semiconductor chip 130. The first hole patterns H1 and the second hole patterns H2 may be disposed adjacently to corners of the semiconductor chip 130, respectively. For example, the first hole patterns H1 may be disposed at ends of the first trench structure TS1, and may be disposed adjacently to a first corner C1 and a third corner C3 of the semiconductor chip 130. The second hole pattern H2 may be disposed between the first line patterns L1 and adjacently to the second corner C2 of the semiconductor chip 130. The first hole patterns H1 and the second hole patterns H2 may be formed to have a circular or elliptical shape in plan view, and may communicate with the first line patterns L1.

As illustrated in FIG. 2, the first line pattern L1 may include an outer wall L1a and an inner wall L1b. The outer wall may refer to a side wall that is relatively distant from the semiconductor chip 130, and the inner wall may refer to a side wall that is relatively close to the semiconductor chip 130. The outer wall L1a of the first line pattern L1 may be perpendicular to an upper surface of the substrate 110, but in some example embodiments is not limited thereto. In some example embodiments, the inner wall L1b of the first line pattern L1 may include an inclined surface. For example, an upper portion of the inner wall L1b may be an inclined surface. In some example embodiments, an entirety of the inner wall L1b may be an inclined surface. The first line pattern L1 may also include a lower surface between the outer wall L1a and the inner wall L1b. The lower surface may be a plane substantially parallel to the upper surface of the substrate 110. In some example embodiments, the lower surface may have a shape such as a downward convex shape, an inverted triangle, or the like.

A depth of the first line pattern L1 may be about 70% to 80% of a thickness of the substrate 110. The depth of the first line pattern L1 may refer to a distance from the upper surface of the substrate 110 to a lower surface of the first line pattern L1. A horizontal width W1 of the first line pattern L1 may be about 4 mm to about 5 mm. The horizontal width may refer to a maximum width along a direction perpendicular to a direction in which the first line pattern L1 extends. For example, the first line pattern L1 illustrated in FIG. 2 may extend in a Y-direction, and the horizontal width W1 of the first line pattern L1 may refer to a distance between a first position X1a where the outer wall L1a meets the upper surface of the substrate 110 and a second position X1b where the inner wall L1b meets the upper surface of the substrate 110 in an X-direction.

In some example embodiments, a horizontal width W2 of the first hole patterns H1 and a horizontal width W3 of the second hole pattern H2 may be greater than the horizontal width W1 of the first line patterns L1. For example, when taken in plan view, the first hole patterns H1 and the second hole pattern H2 may protrude in a horizontal direction from the first line patterns L1. In some example embodiments, the horizontal width W3 of the second hole pattern H2 may be greater than the horizontal width W2 of the first hole patterns H1. In some other example embodiments, the horizontal width W3 of the second hole pattern H2 may be equal to the horizontal width W2 of the first hole patterns H1. For example, the horizontal width W3 of the second hole pattern H2 may be about 8 mm to about 9 mm. The horizontal width W2 of the first hole pattern H1 may be about 5 mm to about 6 mm.

In some example embodiments, the second trench structure TS2 may include second line patterns L2 and third hole pattern H3. The second line patterns L2 may have a bar shape in plan view, and may extend in a horizontal direction along the third side surface S3 and fourth side surface S4 of the semiconductor chip 130. The third hole pattern H3 may be disposed between the second line patterns L2, and may be disposed adjacently to the fourth corner C4 of the semiconductor chip 130. The third hole pattern H3 may be disposed on an opposite side of the center portion of the semiconductor chip 130 from the second hole pattern H2. The third hole pattern H3 may be formed to have a circular or oval shape in plan view, and may communicate with the second line patterns L2.

As illustrated in FIG. 2, the second line pattern L2 may include an outer wall L2a and an inner wall L2b. In some example embodiments, the outer wall L2a and the inner wall L2b of the second line pattern L2 may be inclined surfaces. In some example embodiments, the outer wall L2a and the inner wall L2b may be perpendicular to an upper surface of the substrate 110, and the line pattern may have a rectangular cross-sectional shape.

A depth of the second line pattern L2 may be smaller than a depth of the first line pattern L1. For example, the depth of the second line pattern L2 may be about 50% to about 60% of the thickness of the substrate 110. A horizontal width W4 of the second line pattern L2 may be smaller than the horizontal width W1 of the first line pattern L1. For example, the horizontal width W4 of the second line pattern L2 may be about 2 mm to about 3 mm. The horizontal width may refer to a maximum width along a direction perpendicular to a direction in which the second line pattern L2 extends. For example, the second line pattern L2 illustrated in FIG. 2 may extend in a Y-direction, and the horizontal width W4 of the second line pattern L2 may refer to a distance between a first position X2a where the outer wall L2a meets an upper surface of the substrate 110 and a second position X2b where the inner wall L2b meets an upper surface of the substrate 110 in an X-direction,

The outer wall L2a of the second line pattern L2 may be disposed closer to the semiconductor chip 130 than the outer wall L1a of the first line pattern L1. For example, a distance between the first position X2a and the third side surface S3 of the semiconductor chip 130 may be smaller than a distance between the first position X1a and the first side surface S1 of the semiconductor chip 130.

In some example embodiments, a horizontal width W5 of the third hole pattern H3 may be greater than the horizontal width W4 of the second line patterns L2. For example, when taken in plan view, the third hole pattern H3 may protrude in the horizontal direction from a second line patterns L2. The horizontal width W5 of the third hole pattern H3 may be about 3 mm to about 4 mm.

In some example embodiments, the substrate 110 may include a gap region G between the first trench structure TS1 and the second trench structure TS2. For example, a region in which a trench is not formed between the second line patterns L2 and the first hole pattern H1 may be referred to as a gap region G. The gap region G may be located on a level higher than lower ends of the first trench structure TS1 and the second trench structure TS2, and may be coplanar with an upper surface of the substrate 110.

An underfill 150 may be disposed between the substrate 110 and the semiconductor chip 130. The underfill 150 may fill a space between an upper surface of the substrate 110 and a lower surface of the semiconductor chip 130 and between the chip connection terminals 140. The underfill 150 may also fill a first trench structure TS1 and a second trench structure TS2, and may contact a side surface of the semiconductor chip 130. The underfill 150 may include an insulating polymer material, for example, epoxy resin.

In some example embodiments, the underfill 150 may include a first buried portion 151 and a second buried portion 154 buried within the substrate 110. The first buried portion 151 may refer to a portion of the underfill material filling a first line pattern L1 of the first trench structure TS1, and the second buried portion 154 may refer to a portion of the underfill 150 filling a second line pattern L2 of the second trench structure TS2. The first buried portion 151 and the second buried portion 154 may extend in a horizontal direction along the first line pattern L1 and the second line pattern L2, respectively. In some example embodiments, a horizontal width of the first buried portion 151 may be greater than a horizontal width of the second buried portion 154.

The underfill 150 may further include first protrusions 152, a second protrusion 153, and a third protrusion 155. The first protrusions 152 and the second protrusion 153 may refer to a portion of the underfill 150 filling first hole patterns H1 and a second hole pattern H2, respectively. For example, the first protrusions 152 may be disposed at ends of the first buried portion 151, and may be disposed adjacently to the first corner C1 and the third corner C3 of the semiconductor chip 130. The second protrusion 153 may be disposed between the first buried portions 151 and may be disposed adjacently to the second corner C2 of the semiconductor chip 130. The third protrusion 155 may refer to a portion of the underfill 150 filling a third hole pattern H3. The third protrusion 155 may be disposed between the second line patterns L2, and may be disposed adjacently to the fourth corner C4 of the semiconductor chip 130. The third protrusion 155 may be disposed on an opposite side from the second protrusion 153 with respect to a center portion of the semiconductor chip 130. In some example embodiments, the second protrusion 153 may be larger than the first protrusions 152, and the first protrusions 152 may be greater than the third protrusion 155.

The encapsulant 160 may cover the substrate 110, the semiconductor chip 130, and the underfill 150. The encapsulant 160 may be a resin containing epoxy or polyimide. For example, the resin may include a bisphenol-group epoxy resin, a polycyclic aromatic epoxy resin, an o-cresol novolac epoxy resin, a biphenyl-based epoxy resin, or a naphthalene-group epoxy resin.

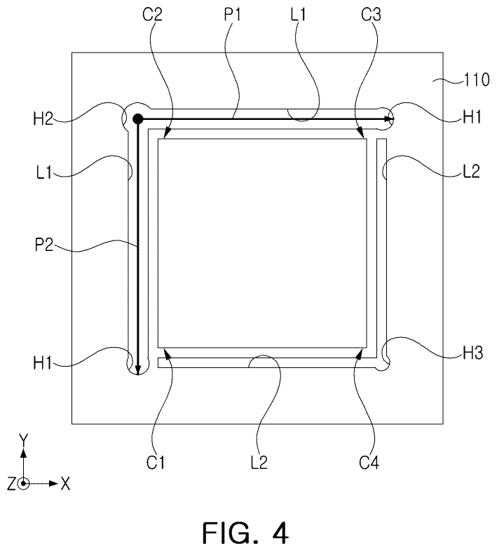

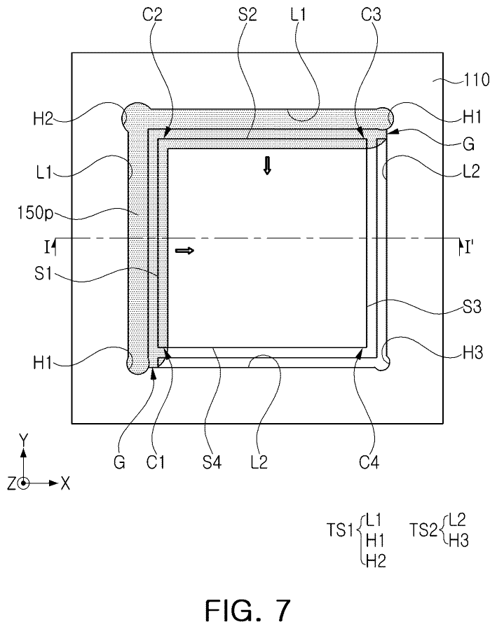

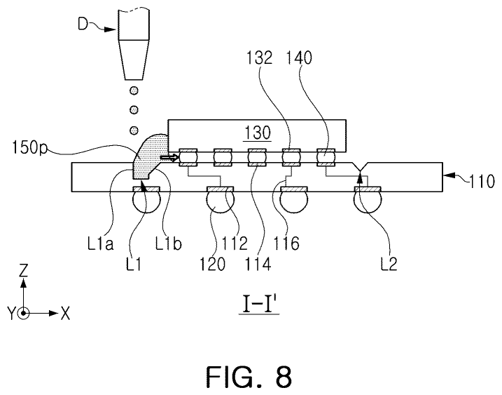

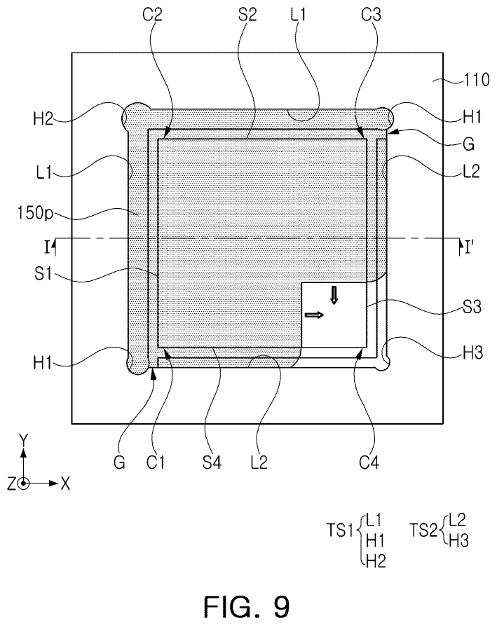

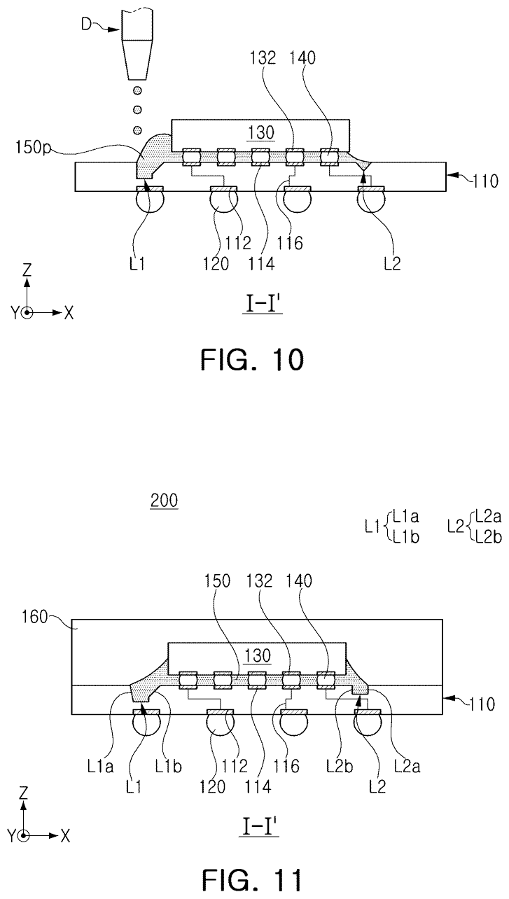

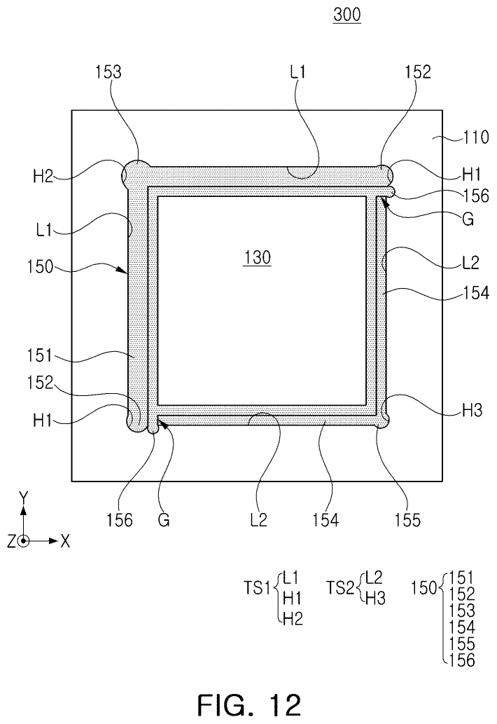

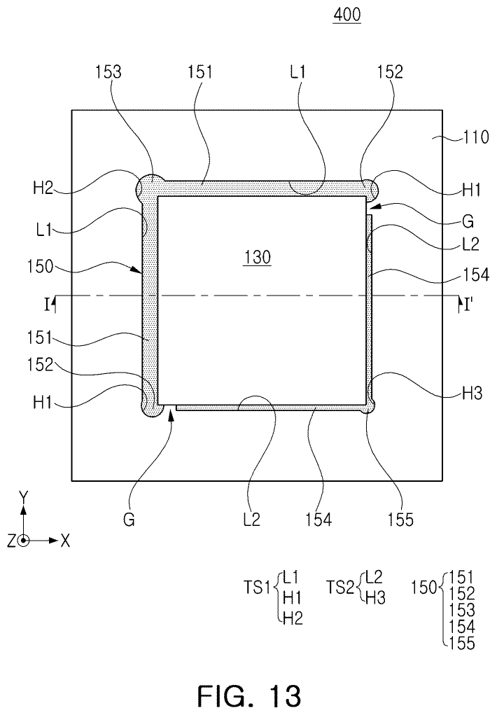

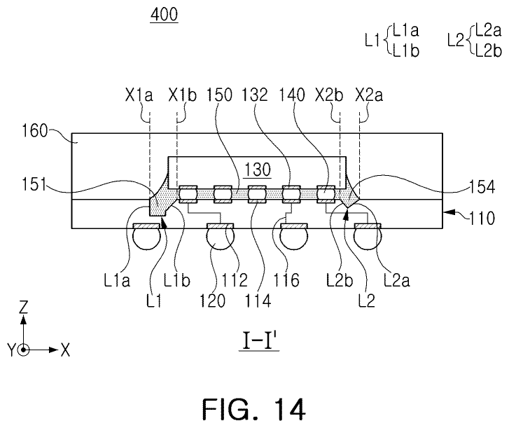

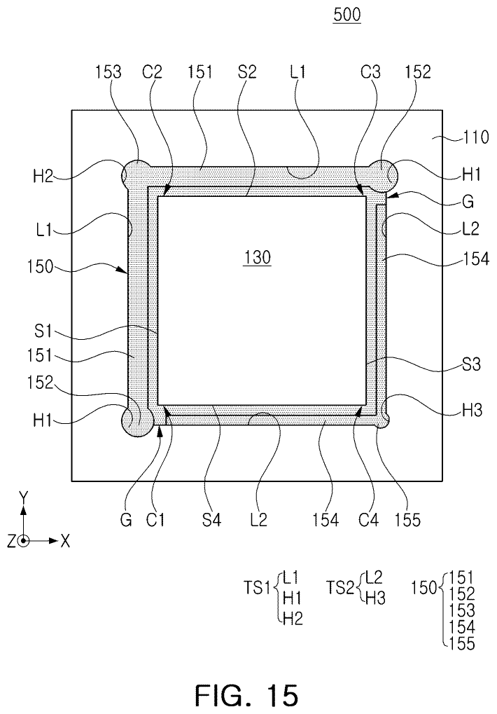

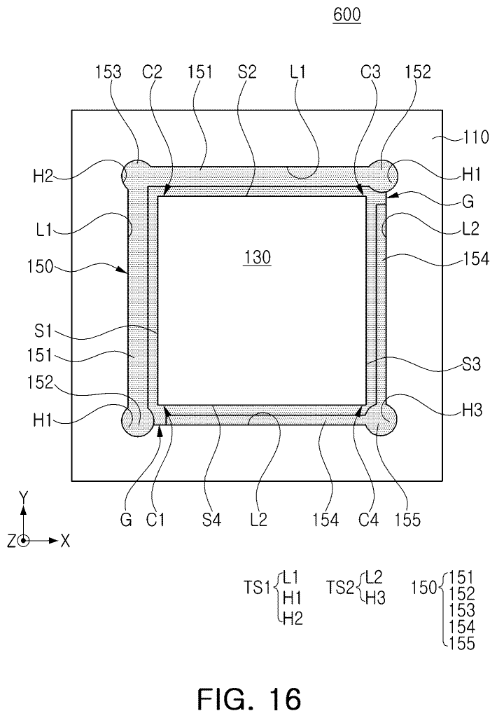

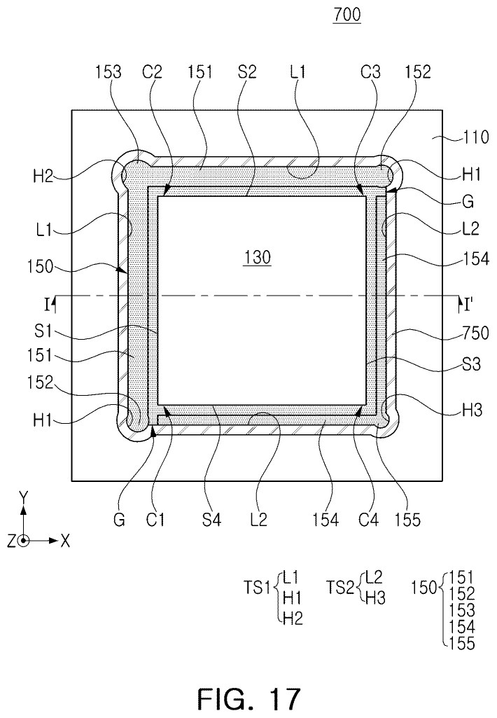

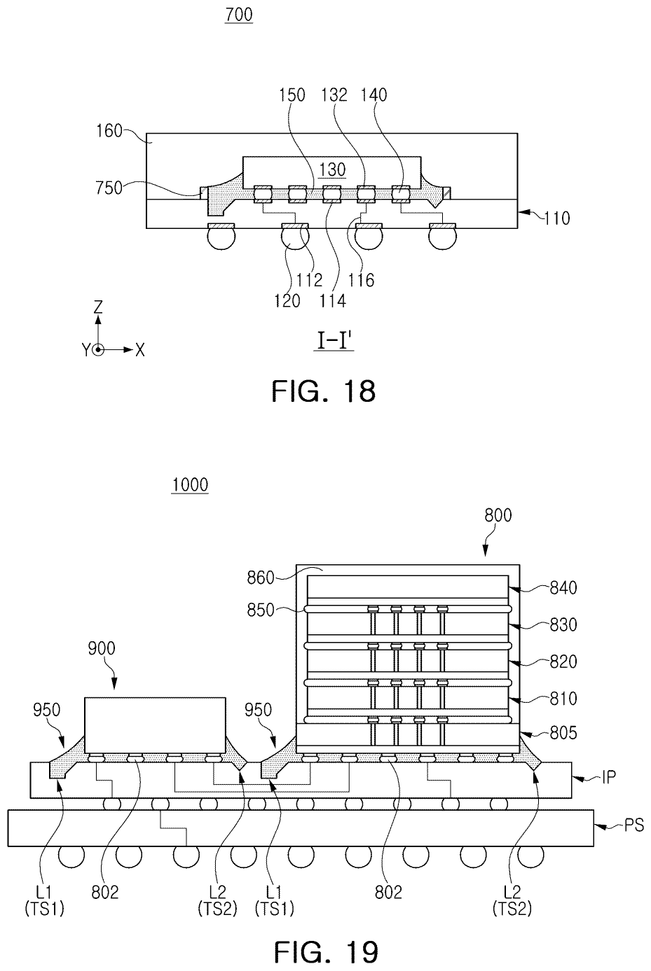

FIGS. 4 to 10 are diagrams illustrating a method of forming an underfill according to example embodiments. FIGS. 4 to 6 are diagrams illustrating a method of dispensing an underfill material using a dispenser. FIGS. 7 to 10 illustrate that an underfill is formed. FIGS. 8 and 10 are vertical cross-sectional views along line I-I illustrated in FIGS. 7 and 9, respectively.

Referring to FIGS. 4 to 6, forming an underfill 150 may include discharging an underfill material 150p onto a first trench structure TS1 using a dispenser D (see FIG. 8).

Referring to FIG. 4, in some example embodiments, the dispenser D may move along a first path P1 and a second path P2 and discharge an underfill material 150p. For example, the dispenser D may move from the second hole pattern H2 along the first path P1 to a first hole pattern H1, adjacent to the third corner C3 along the first line pattern L1 in the X-direction and discharge the underfill material 150p. Thereafter, the dispenser D may move from the second hole pattern H2 along the second path P2 to a first hole pattern H1, adjacent to the first corner C1 along the first line pattern L1 in the Y-direction and discharge the underfill material 150p. The dispenser D may repeat a process of discharging the underfill material 150p along the first path P1 and the second path P2 multiple times.

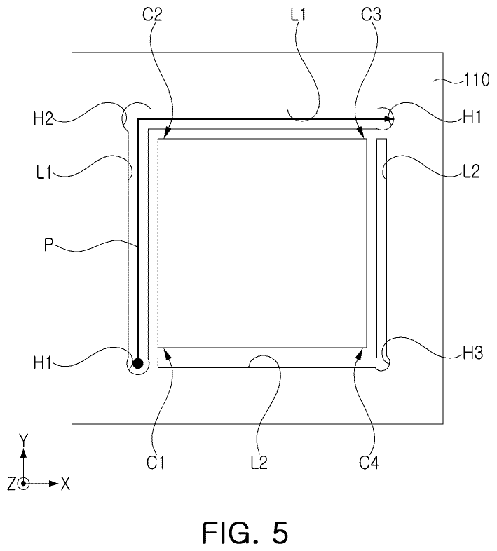

Referring to FIG. 5, in some example embodiments, the dispenser D may move along a path P and discharge an underfill material 150p. For example, the dispenser D move from a first hole pattern H1, adjacent to the first corner C1, along the path P through the second hole pattern H2, to a first hole pattern H1, adjacent to the third corner C3 and discharge the underfill material 150p. The dispenser D may repeat the process of discharging the underfill material 150p along the path P multiple times.

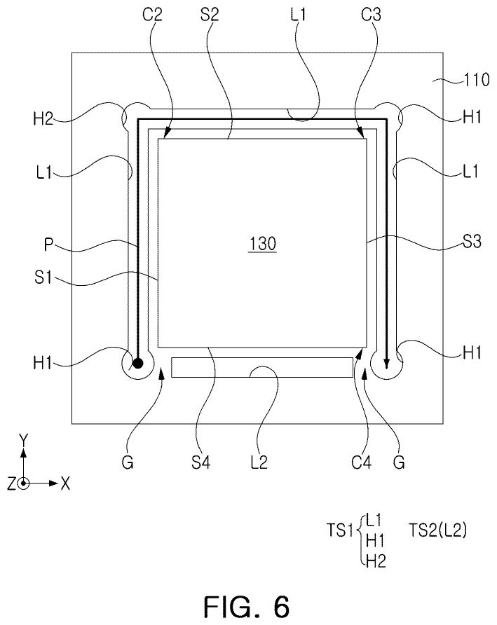

Referring to FIG. 6, in some example embodiments, the dispenser D may move along the path P and discharge the underfill material 150p. For example, the dispenser D may move along a first side surface S1, a second side surface S2, and a third side surface S3 of the semiconductor chip 130 along the path P and discharge the underfill material 150p. In some example embodiments, shapes of the first trench structure TS1 and the second trench structure TS2 may be different from those illustrated in FIG. 1. For example, the first trench structure TS1 may include first line patterns L1 extending along the first side surface S1, the second side surface S2, and the third side surface S3 of the semiconductor chip 130, first hole patterns H1 adjacent to a first corner C1, a third corner C3, and a fourth corner C4 of the semiconductor chip 130, and a second hole pattern H2 adjacent to the second corner C2 of the semiconductor chip 130. The first line patterns L1 may connect the first hole patterns H1 and the second hole pattern H2 to each other. In some example embodiments, the second trench structure TS2 may include a second line pattern L2 extending along the fourth side surface S4 of the semiconductor chip 130. Gap regions G may be disposed on both sides of the second line pattern L2, and the second line pattern L2 may be spaced apart from the first trench structure TS1 with the gap regions G therebetween. In some example embodiments, a horizontal width of the first line patterns L1 may be the same as a horizontal width of the second line patterns L2.

The dispenser D may discharge an underfill material 150p on the first trench structure TS1 along the path P, and the underfill material 150p may move from the first side surface S1, the second side surface S2, and the third side surface S3 of the semiconductor chip 130 toward the fourth side surface S4 to fill the second trench structure TS2. The dispenser D may repeat a process of discharging the underfill material 150p along the path P multiple times.

Referring to FIGS. 7 and 8, an underfill material 150p may be discharged on the first line patterns L1, the first hole patterns H1, and the second hole patterns H2 by the dispenser D. A diameter of the underfill material 150p discharged from the dispenser D may be about 0.1 mm to about 0.3 mm. According to some example embodiments of the inventive concepts, since an inner wall L1b of the first line pattern L1 has an inclined surface, the inner wall L1b may be induced so that the underfill material 150 discharged on the first trench structure TS1 flows toward the semiconductor chip 130.

The discharged underfill material 150p may be stacked and contact a side surface of the semiconductor chip 130. Thereafter, it may flow between the substrate 110 and the semiconductor chip 130 due to capillary action. For example, the underfill material 150p may flow from the first side surface S1 and the second side surface S2 of the semiconductor chip 130 toward the third side surface S3 and the fourth side surface S4.

Referring to FIGS. 9 and 10, a portion of the underfill material 150p flowing along the lower surface of the semiconductor chip 130 may fill the second line pattern L2. The underfill material 150p may flow toward the fourth corner C4 of the semiconductor chip 130. Thereafter, the underfill 150 may be formed by filling the third hole pattern H3 with the underfill material 150p.

Since the underfill material 150p is stacked on a side surface of the semiconductor chip 130, and then spreads to the lower surface of the semiconductor chip 130 due to capillary action, a rate at which the underfill material 150p flows may not be uniform. For example, a rate at which the underfill material 150p spreads near a corner portion of the semiconductor chip 130 may be slower than a rate at which the underfill material 150p spreads near a center portion of the side surface of the semiconductor chip 130. However, according to some example embodiments of the inventive concepts, as illustrated in FIG. 7, first hole patterns H1 and second hole pattern H2 may be disposed respectively, adjacently to the first corner C1, the second corner C2, and the third corner C3 of the semiconductor chip 130, and the first hole patterns H1 and the second hole pattern H2 may have a larger horizontal width than the first line patterns L1. The underfill material 150p may be stacked on the upper surface of the substrate 110 after sufficiently filling the first hole patterns H1, the second hole pattern H2, and the first line patterns L1, and then may flow into the lower surface of the semiconductor chip 130. Therefore, according to some example embodiments of the inventive concepts, the rate at which the underfill material 150p spreads near the corner portion of the semiconductor chip 130 may be substantially the same as the rate at which the underfill material 150p spreads near the center portion of the side surface of the semiconductor chip 130. Therefore, when forming the underfill 150, it is possible to limit and/or prevent voids from remaining in the underfill material 150p.

According to some example embodiments of the inventive concepts, a gap region G in which a trench is not formed may be disposed between the second line patterns L2 and the first hole patterns H1. When the second line patterns L2 and the first hole patterns H1 communicate without the gap region G, the underfill material 150p may flow from the four side surfaces of the semiconductor chip 130 toward the center portion of the semiconductor chip 130, respectively. However, since some example embodiments of the inventive concepts include a gap region G on the upper surface of the substrate 110, voids can be limited and/or prevented from remaining on the center portion of the lower surface of the semiconductor chip 130.

According to some example embodiments of the inventive concepts, the underfill material 150p may flow into the first trench structure TS1 and the second trench structure TS2, so that the underfill material 150p may be limited and/or prevented from overflowing onto the semiconductor chip 130 and covering the upper surface of the semiconductor chip 130. Since the underfill material 150p may flow into the first trench structure TS1 and the second trench structure TS2, it may be limited and/or prevented from incompletely covering the lower surface of the semiconductor chip 130. Alternatively, it is possible to limit and/or prevent the underfill material 150p from being excessively discharged and spreading away from the side surface of the semiconductor chip 130.

Since the underfill material 150p is discharged first on the first trench structure TS1, the dispenser D may discharge a larger amount of the underfill material 150p at one time. Accordingly, the time required to form the underfill 150 can be shortened.

FIGS. 11 and 12 are plan views of a semiconductor package according to some example embodiments.

Referring to FIG. 11, the substrate 110 of the semiconductor package 200 may include a first line pattern L1 and a second line pattern L2 on an upper surface thereof. In some example embodiments, both an outer wall L1a and an inner wall L1b of the first line pattern L1 may include an inclined surface. In some example embodiments, an outer wall L2a and an inner wall L2b of the second line pattern L2 may be perpendicular to the upper surface of the substrate 110. The second line pattern L2 may include a lower surface, substantially parallel to the upper surface of the substrate 110 between the outer wall L2a and the inner wall L2b. Shapes of cross-sectional views of the first line pattern L1 and the second line pattern L2 shown in FIG. 11 are examples, and some other example embodiments are not limited thereto.

Referring to FIG. 12, the semiconductor package 300 may include an underfill 150 disposed between the substrate 110 and the semiconductor chip 130. In some example embodiments, the underfill 150 may further include fourth protrusions 156 covering a gap region G and protruding in a horizontal direction. For example, the fourth protrusions 156 may be disposed between the second line patterns L2 and the first hole patterns H1. In plan view, the fourth protrusions 156 may protrude in a direction, away from the semiconductor chip 130.

FIG. 13 is a plan view of a semiconductor package according to some example embodiments. FIG. 14 is a vertical cross-sectional view taken along line I-I′ of the semiconductor package illustrated in FIG. 13.

Referring to FIGS. 13 and 14, a first trench structure TS1 and a second trench structure TS2 of the semiconductor package 400 may overlap at least a portion of the semiconductor chip 130 vertically (Z direction). For example, in a cross-sectional view, a side surface of the semiconductor chip 130 may be disposed between a first position X1a and a second position X1b, and at least a portion of an inner wall L1b of a first line pattern L1 may vertically overlap the semiconductor chip 130. The side surface of the semiconductor chip 130 may be disposed between a first position X2a and a second position X2b, and at least a portion of an inner surface L2b of a second line pattern L2 may vertically overlap the semiconductor chip 130. In plan view, at least a portion of first hole patterns H1, a second hole pattern H2, and a third hole pattern H3 may vertically overlap corners C1, C2, C3, and C4 of the semiconductor chip 130.

FIGS. 15 and 16 are plan views of semiconductor packages according to some example embodiments.

Referring to FIG. 15, the substrate 110 of the semiconductor package 500 may include a first trench structure TS1 and a second trench structure TS2 formed on an upper surface thereof. In some example embodiments, horizontal widths of first hole patterns H1 and a second hole pattern H2 of the first trench structure TS1 may be equal to each other. A horizontal width of a third hole pattern H3 of a second trench structure TS2 may be smaller than the horizontal width of the first hole patterns H1 and the second hole pattern H2.

Referring to FIG. 16, the substrate 110 of the semiconductor package 600 may include a first trench structure TS1 and a second trench structure TS2 formed on an upper surface thereof. In some example embodiments, the horizontal widths of the first hole patterns H1, the second hole pattern H2, and the third hole pattern H3 may be equal to each other.

FIG. 17 is a plan view of a semiconductor package according to some example embodiments. FIG. 18 is a vertical cross-sectional view taken along line I-I′ of the semiconductor package shown in FIG. 17.

Referring to FIGS. 17 and 18, the semiconductor package 700 may include a dam structure 750 surrounding a semiconductor chip 130, a first trench structure TS1, a second trench structure TS2, and an underfill 150. For example, the dam structure 750 may extend in a horizontal direction along the first trench structure TS1 and the second trench structure TS2. Since the dam structure 750 is disposed along the first trench structure TS1 and the second trench structure TS2, it can limit and/or prevent the underfill 150 from being unfilled between the semiconductor chip 130 and the substrate 110. The underfill 150 may contact a side surface of the dam structure 750. A shape of the dam structure 750 shown in FIG. 17 is an example, and other example embodiments are not limited thereto. In some example embodiments, the dam structure 750 may have various shapes, such as square, circular, oval, or the like. The dam structure 750 may include an insulating material such as resin or silicon, or a metal material such as aluminum (Al) or copper (Cu).

FIG. 19 is a vertical cross-sectional view of a semiconductor package according to some example embodiments of the inventive concepts.

Referring to FIG. 19, a semiconductor package 1000 of the inventive concepts may be a high bandwidth memory (HBM) package. The semiconductor package 1000 may include a package substrate PS, an interposer IP mounted on the package substrate PS, and a memory package 800 and a processor chip 900 mounted on the interposer IP. The interposer IP may electrically connect the memory package 800 and the processor chip 900. Chip connection terminals 802 connected to the memory package 800 and the processor chip 900 may be disposed on the interposer IP.

The interposer IP may have the same or similar structure as the substrate 110 of the semiconductor packages 100, 200, 300, 400, 500, 600, and 700 according to example embodiments of the inventive concepts. The interposer IP may be referred to as a ‘substrate 110’. A memory package 800 and a processor chip 900 may be mounted on the interposer IP. An upper surface of the interposer IP may include the first trench structures TS1 and second trench structures TS2 described in FIGS. 1A to 3 and 11 to 18. For example, the memory package 800 may be surrounded by a first line pattern L1 of the first trench structure TS1 and a second line pattern L2 of the second trench structure TS2. The processor chip 900 may be surrounded by the first line pattern L1 of the first trench structure TS1 and the second line pattern L2 of the second trench structure TS2. Although not illustrated, the first trench structures TS1 may further include first hole patterns H1 and second hole patterns H2. The second trench structure TS2 may further include a third hole pattern H3. The semiconductor chip 130, memory package 800, and processor chip 900 may be referred to as a ‘semiconductor structure.’

The semiconductor package 1000 may further include an underfill 950 disposed between the interposer IP and the memory package 800 and between the interposer IP and the processor chip 900. The underfills 950 may fill the first trench structure TS1 and the second trench structure TS2. The underfill 950 may have the same or similar structure as the underfill 150 described with reference to FIGS. 1A to 3.

The memory package 800 may include a buffer chip 805, a first semiconductor device 810, a second semiconductor device 820, a third semiconductor device 830, and a fourth semiconductor device 840, sequentially stacked.

In some example embodiments, the buffer chip 805 may be a type of semiconductor chip 130, different from the first to fourth semiconductor devices 810, 820, 830, and 840. For example, the buffer chip 805 may be a logic chip, and the first to fourth semiconductor devices 810, 820, 830, and 840 may be memory chips. In some example embodiments, the memory package 800 may include a plurality of semiconductor elements (e.g., memory chips) that are stacked on buffer chip 805. The logic chip may include a microprocessor, analog element, or digital signal processor. The memory chip may include a volatile memory chip such as Dynamic Random Access Memory (DRAM) or Static Random Access Memory (SRAM), or a non-volatile memory chip such as Phase-change Random Access Memory (PRAM), Magnetoresistive Random Access Memory (MRAM), Ferroelectric Random Access Memory (FeRAM), or Resistive Random Access Memory (RRAM).

The memory package 800 may further include an adhesive layer 850 and an encapsulant 860. The adhesive layer 850 may be disposed between the buffer chip 805 and the first semiconductor device 810 and between the first to fourth semiconductor devices 810, 820, 830, and 840. The adhesive layer 850 may be non-conductive film (NCF) or non-conductive paste (NCP). The encapsulant 860 may be a resin containing epoxy or polyimide. For example, the resin may include a bisphenol-group epoxy resin, a polycyclic aromatic epoxy resin, an o-Cresol novolac epoxy resin, a biphenyl-based epoxy resin, or a naphthalene-group epoxy resin.

The processor chip 900 may be a central processing unit (CPU), a graphics processing unit (GPU), a mobile application, or a digital signal processor (DSP) chip.

As set forth above, according to some example embodiments of the inventive concepts, line patterns of trench structures may be formed on an upper surface of a substrate along side surfaces of a semiconductor chip.

Accordingly, an underfill material discharged from a dispenser can be limited and/or prevented from covering an upper surface of a semiconductor chip. Hole patterns of trench structures may be formed on the upper surface of the substrate along corners of the semiconductor chip.

Since the hole patterns have a larger horizontal width than line patterns, underfill material can be sufficiently stacked near the corners of the semiconductor chip. Therefore, it is possible to limit and/or prevent an underfill from being unfilled or voids remaining within the underfill.

While example embodiments have been shown and described above, it will be apparent to those skilled in the art that modifications and variations could be made without departing from the scope of the inventive concepts as defined by the appended claims.

What is claimed is:

1. A semiconductor package, comprising:
a substrate defining a first trench structure and a second trench structure in an upper surface of the substrate;
a semiconductor chip disposed on the substrate; and
an underfill filling a space between the substrate and the semiconductor chip,
the first trench structure and the second trench structure surrounding the semiconductor chip,
the first trench structure including at least one first line pattern extending along at least one side surface of the semiconductor chip,
the second trench structure including at least one second line pattern extending along at least one other side surface of the semiconductor chip, and
a horizontal width of the at least one first line pattern is greater than a horizontal width of the at least one second line pattern.

2. The semiconductor package of claim 1, wherein the underfill fills the first trench structure and the second trench structure.

3. The semiconductor package of claim 1, wherein the horizontal width of the at least one first line pattern is about 4 mm to about 5 mm.

4. The semiconductor package of claim 1, wherein the horizontal width of the at least one second line pattern is about 2 mm to about 3 mm.

5. The semiconductor package of claim 1, wherein a depth of the at least one first line pattern is greater than a depth of the at least one second line pattern.

6. The semiconductor package of claim 1, wherein a portion of an inner wall of the at least one first line pattern is an inclined surface.

7. The semiconductor package of claim 1, wherein an outer wall of the at least one second line pattern is closer to the semiconductor chip than an outer wall of the at least one first line pattern.

8. The semiconductor package of claim 1, wherein portions of the first trench structure and portions of the second trench structure vertically overlap the semiconductor chip.

9. The semiconductor package of claim 1, wherein the first trench structure further includes a first hole pattern at an end of the first trench structure, the first hole pattern adjacent to one of corners of the semiconductor chip, and
a horizontal width of the first hole pattern is greater than the horizontal width of the at least one first line pattern.

10. The semiconductor package of claim 9, wherein the substrate includes a gap region without a trench structure, the gap region between the first hole pattern and the at least one second line pattern.

11. The semiconductor package of claim 9, wherein the at least one first line pattern of the first trench structure includes a plurality of first line patterns, and the first trench structure further includes a second hole pattern betwveen the plurality of first line patterns, the second hole pattern adjacent to another one of the corners of the semiconductor chip, and
a horizontal width of the second hole pattern is greater than the horizontal width of the plurality of first line patterns.

12. The semiconductor package of claim 11, wherein the horizontal width of the second hole pattern is greater than or equal to the horizontal width of the first hole pattern.

13. The semiconductor package of claim 9, wherein the at least one second line pattern of the second trench structure includes a plurality of second line patterns, and the second trench structure further includes a second hole pattern between the plurality of second line patterns, the second hole pattern adjacent to another one of the corners of the semiconductor chip, and
a horizontal width of the second hole pattern is greater than the horizontal width of the plurality of second line patterns.

14. A semiconductor package, comprising:
a substrate defining a first trench structure and a second trench structure in an upper surface of the substrate;
a semiconductor chip on the substrate; and
an underfill filling a space between the substrate and the semiconductor chip,
the first trench structure and the second trench structure surrounding the semiconductor chip,
the first trench structure including at least one first line pattern extending along at least one side surface of the semiconductor chip,
the second trench structure including at least one second line pattern extending along at least one other side surface of the semiconductor chip,
the underfill including a first buried portion filling the at least one first line pattern and a second buried portion filling the at least one second line pattern, and
a horizontal width of the first buried portion is greater than a horizontal width of the second buried portion.

15. The semiconductor package of claim 14, wherein the underfill further includes a first protrusion and a second protrusion protruding from the first buried portion in a horizontal direction, the first and second protrusions adjacent to corners of the semiconductor chip.

16. The semiconductor package of claim 15, wherein the underfill further includes a third protrusion protruding from the second buried portion in the horizontal direction, the third protrusion adjacent to another one of the corners of the semiconductor chip.

17. The semiconductor package of claim 15, wherein the underfill further includes a third protrusion protruding in a direction away from the semiconductor chip, the third protrusion between the first protrusion and the second buried portion.

18. The semiconductor package of claim 14, further comprising:
a dam structure on the substrate, the dam structure surrounding the first trench structure and the second trench structure, and
the underfill is in contact with a side surface of the dam structure.

19. A semiconductor package, comprising:
a substrate defining a first trench structure and a second trench structure in an upper surface of the substrate;
a semiconductor structure on the substrate;
chip connection terminals between the substrate and the semiconductor structure; and
an underfill filling a space between the substrate and the semiconductor structure and between the chip connection terminals,
the first trench structure and the second trench structure surrounding the semiconductor structure,
the first trench structure including
first line patterns extending along a first side surface and a second side surface of the semiconductor structure,
first hole patterns adjacent to a first corner and a third corner of the semiconductor structure, the first hole patterns communicating with the first line patterns, and
a second hole pattern communicating with the first line patterns, the second hole pattern adjacent to a second corner of the semiconductor structure,
the second trench structure including second line patterns extending along a third side surface and a fourth side surface of the semiconductor structure, the third side surface opposite to the first side surface, and the fourth side surface opposite to the second side surface, and
a horizontal width of the first line patterns is greater than a horizontal width of the second line patterns.

20. The semiconductor package of claim 19, wherein the semiconductor structure includes a plurality of semiconductor elements sequentially stacked on a buffer chip.
